(19) United States
(12) Patent Application Publication
(10) Pub. No.: US 2025/0059991 A1
(43) Pub. Date: Feb. 20, 2025

(54) BOARD ASSEMBLY DEVICE

(71) Applicant: HANWIT PRECISION INDUSTRIES LTD., New Taipei (TW)

(72) Inventors: Ying-Chih TSENG, New Taipei (TW); Ming-De WU, New Taipei (TW); Ching-Kai CHANG, New Taipei (TW)

(21) Appl. No.: 18/451,591

(22) Filed: Aug. 17, 2023

(51) Int. Cl. F16B 5/02

(52) U.S. Cl. CPC F16B 5/02

(57) ABSTRACT

A board assembly device includes a base including a base body having a through hole and a spiral slideway and a positioning member having a joint portion assembled on the through hole, a fixed portion stopped outside the through hole and a locking screw hole therein, a movable seat including a rotating member and a fastening member with a positioning hole, the rotating member having an insertion rod penetrating into the through hole, a sliding rod with a shaft hole for sliding along the slideway, and an accommodating groove for the embedding and fixation of the fastening member, and a connecting member having a head exposed outside the fastening member, a shank inserted into the positioning hole and a screw rod passing through the shaft hole and the through hole and then locked in the locking screw hole.

### BACKGROUND OF THE INVENTION

### 1. Field of the Invention

The present invention provides a board assembly device, especially a board assembly device that drives a rotating member on base to rotate and lift through a connecting member. It is to assemble the rotating member of a movable seat on the base body of the base, and use the connecting member to pass through the rotating member, so that the rotating member can be driven to slide up and down at the base body through the rotation of the connecting member to achieve the purpose of convenient operation of the rotating member located at the base body to rotate, lift and move.

### 2. Description of the Related Art

General boards (board-to-board) are locked using positioning screws with knobs, collars and screws when assembling and joining, and are used for boards that can be used for machine tools or other board-to-board connections. However, these machine tools need to use boards for locking joints, which can be assembled, locked, and disassembled using boards. When the power unit crashes or fails or is damaged, or the speed adjustment device changes or adjusts the speed, the boards are removed for related maintenance and adjustment operations. The boards are locked by a plurality of positioning screws, so it is easy to cause the positioning screws to fall off or be lost during the disassembly process, and the boards cannot be re-locked back to their original position, which affects the inconvenience and trouble of assembly and disassembly.

Furthermore, with the continuous innovation and progress of computer technology, the application level of computers or various electronic and electrical products is more extensive, and the use functions continue to expand and increase. In computers or electronic and electrical products, the circuit layout, central processing unit, chip and various electronic components used to handle various operations, calculations, execution, analysis and other functions must also be appropriately expanded and increased. Therefore, the circuit boards configured with circuit layout, central processing unit, chips and various electronic components will also expand and increase the area and scope of use with the application functions of the computer. However, in the case of limited internal space available in computers or electronic and electrical products, the circuit boards that control the start-up and operation of computers or electronic and electrical products cannot expand the area. In order to solve the problem of circuit board application, the industry expands the application area of circuit boards through the technology of assembling circuit boards in a laminated board-to-board manner. It uses at least one set of board-to-board connectors for electrical plug-in assembly between two opposite circuit boards for the transmission of electronic signals or power between two opposite circuit boards. In actual use and implementation, when one or two circuit boards need to be repaired, tested or replaced, at least one set of board-to-board connectors between the two opposite circuit boards must be disassembled and separated one by one. Therefore, great attention must be paid to the disassembling force of the two opposing circuit boards. If there is a slight excessive force, it may cause loosening, peeling, falling off or separation between the circuit boards and the board-to-board connectors, resulting in poor electrical connection between the circuit boards and the board-to-board connectors, and failure to transmit electronic signals, or causing the circuit boards to collide or push against other surrounding electronic products or electronic components, or causing damage or failure to the circuit boards or board-to-board connectors. For the practical application between two relative circuit boards and board-to-board connectors, there are still many deficiencies that need to be improved.

Therefore, how to solve the operational problems and troubles of the current two relative circuit boards and board-to-board electrical connectors during assembly and disassembly, and the problems of being easily to cause damage to the circuit board or board-to-board connectors, that is the direction that relevant manufacturers engaged in this industry are eager to study and improve.

### SUMMARY OF THE INVENTION

Therefore, in view of the above-mentioned problems and deficiencies, the inventor collected relevant information, evaluated and considered in many ways, and based on years of experience accumulated in this industry, through continuous creation and modification, the designed the invention of this board assembly device.

The main object of the present invention is to provide a board assembly device, which comprises a base, a movable seat, and a connecting member. The base comprises a base body and a positioning member assembled at the bottom of the base body. The base body comprises a through hole inside and a slideway extending obliquely in a spiral shape on the outside. The positioning member comprises a joint portion assembled and positioned on one end of the through hole, a fixed portion located on one side of the joint portion and stopped outside the through hole, and a locking screw hole provided therein. The movable seat is movably assembled outside the base body, comprising a rotating member and a fastening member. The rotating member comprises an insertion rod extended from the bottom side thereof for penetrating into the through hole of the base body, a sliding rod extended from the bottom side and spaced from the insertion rod at one side for sliding along the slideway of the base body, a shaft hole located in the insertion rod and an accommodating groove recessed on the opposing top side thereof for the embedding and fixation of the fastening member. The fastening member has a positioning hole formed therein. The connecting member comprises a head and a shank extending from one side of the head. The shank is used to be inserted into the positioning hole of the fastening member. The head is exposed to the outside of the fastening member. The connecting member further comprising a screw rod extended from the shank opposite to the head. The screw rod passes through the shaft hole of the rotating member, and passes through the through hole of the base body of the base, and then is locked in the locking screw hole of the positioning member. It can be used inside the rotating member, the base body and the positioning member to achieve the purpose of using the connecting member to operate the movable seat to rotate up and down at the base.

Another object of the present invention is to provide a board assembly device, wherein a lower limit stop wall on one side of the base body of the base, a higher limit stop wall on an opposite side of the base body of the base, and a limit hole with reduced diameter on the end of the through hole near the higher limit stop wall, and the slideway extends spirally from the lower limit stop wall to the higher limit stop wall. Furthermore, the side of the insertion rod of the rotating member of the movable seat that penetrates into the through hole is provided with an expansion ring body, which is to be held against an inner side of the limit hole to form a limit, and the other side of the through hole is to be used for fastening and embedding of meshing teeth of the joint portion of the positioning member. Furthermore, the diameter of the through hole of the base bod is smaller than the outer diameter of the joint portion of the positioning member.

Still another object of the present invention is to provide a board assembly device, wherein the bottom side of the rotating member is protruded with the insertion rod that reduces the diameter, and the bottom side of the rotating member is also provided with the sliding rod extending in the same direction as the insertion rod. The rotating member further comprises a ring convex located on the top side thereof outside the shaft hole, and the accommodating groove is recessed in the ring convex for the fastening member to be embedded in a tight fit position. Furthermore, the shank of the connecting member is mounted with a gasket, and the diameter of the gasket is larger than the outer diameter of the ring convex.

Still another object of the present invention is to provide a board assembly device, wherein the shank of the connecting member is passed through the positioning hole of the fastening member to form a tight fit for the fastening member and the rotating member to rotate and displace along with the connecting member, and the fastening member is made of a flexible material selected from the group of soft plastic, silicone, rubber and nylon.

### BRIEF DESCRIPTION OF THE DRAWINGS

FIG. 1 is a three-dimensional appearance diagram of the present invention.

FIG. 2 is a three-dimensional exploded view of the present invention.

FIG. 3 is a three-dimensional exploded view of another perspective of the present invention.

FIG. 4 is a side sectional view of the present invention.

FIG. 5 is a side sectional view of the implementation of a preferred embodiment of the present invention.

FIG. 6 is a side sectional view of the preferred embodiment of the present invention when it is disassembled (I).

FIG. 7 is a side sectional view of the preferred embodiment of the present invention when it is disassembled (II).

FIG. 8 is a disassembled side sectional view of the preferred embodiment of the present invention.

### DETAILED DESCRIPTION OF THE PREFERRED EMBODIMENT

In order to achieve the above-mentioned objects and effects, the technical means adopted in the present invention, its structure, and the method of implementation, etc., are hereby drawn in detail to illustrate the features and functions of the preferred embodiment of the present invention as follows, so as to facilitate a complete understanding.

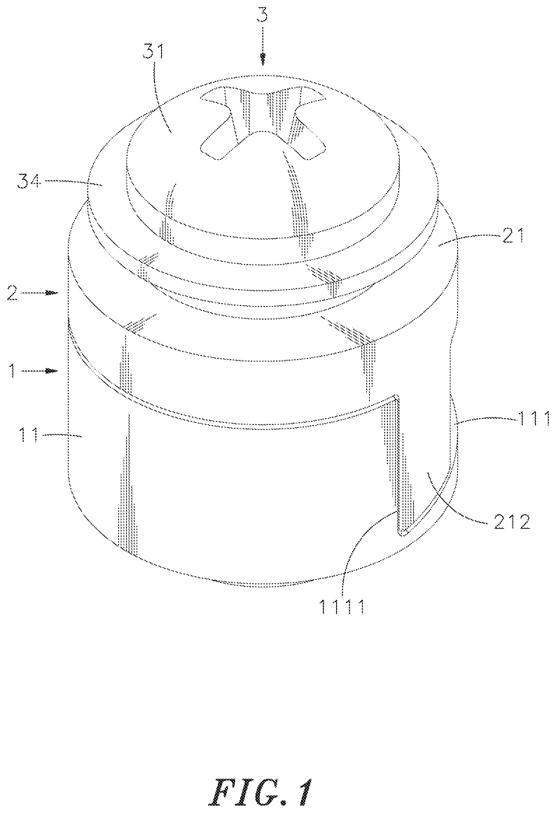

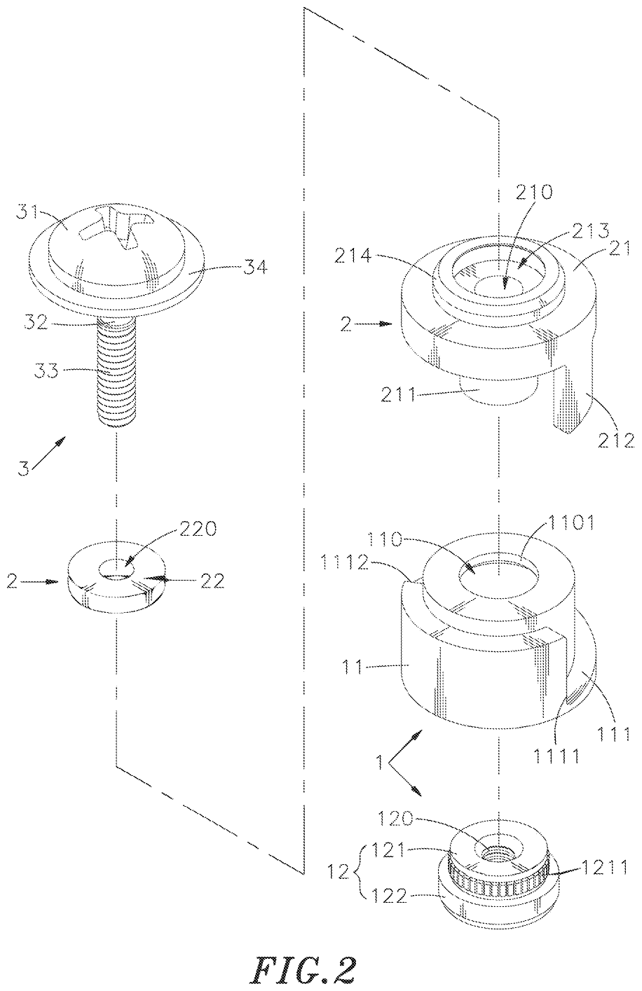

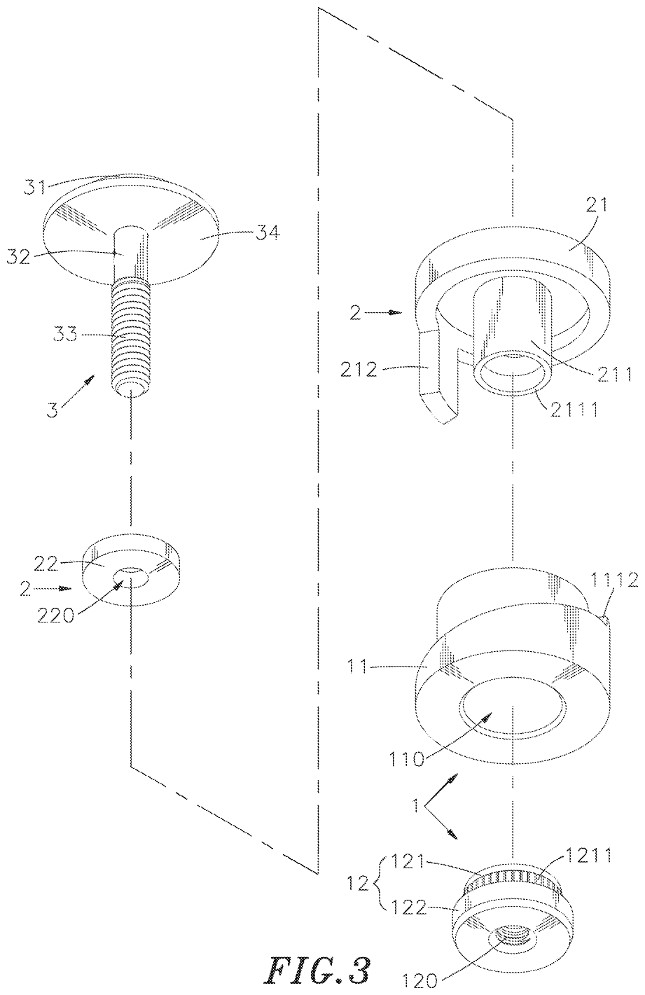

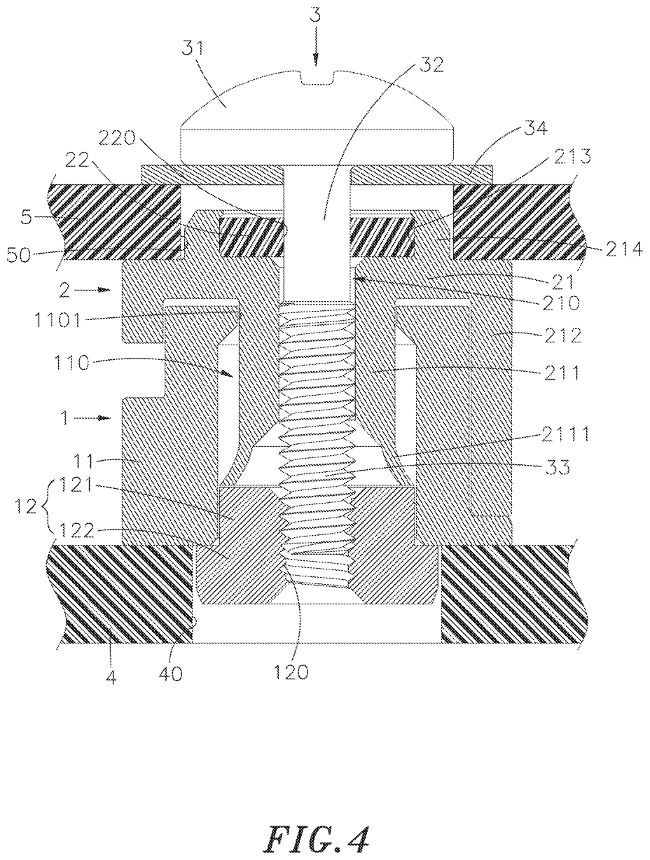

Please refer to FIGS. 1, 2, 3, and 4, which are three-dimensional appearance diagram, three-dimensional exploded view, three-dimensional exploded view from another perspective, and side sectional view of the present invention. It can be clearly seen from the figures that the board assembly device of the present invention comprises a base 1, a movable seat 2 and a connecting member 3.

The base 1 comprises a base body 11 and a positioning member 12 assembled at the bottom of the base body 11. The base body 11 comprises a through hole 110 inside, and a slideway 11 extending obliquely in a spiral shape on the outside. The positioning member 12 comprises a joint portion 121 assembled and positioned on one end of the through hole 110, a fixed portion 122 located on one side of the joint portion 121 and stopped outside the through hole 110, and a locking screw hole 120 provided therein.

The movable seat 2 is assembled outside the base body 11, comprising a rotating member 21 and a fastening member 22. The rotating member 21 comprises an insertion rod 211 extended from a bottom side thereof for penetrating into the through hole 110 of the base body 11, a sliding rod 212 extended from the bottom side and spaced from the insertion rod 211 at one side for sliding along the slideway 111 of the base body 11, a shaft hole 210 located in the insertion rod 211, and an accommodating groove 213 recessed on an opposing top side thereof for the embedding and fixation of the fastening member 22. The fastening member 22 has a positioning hole 220 formed therein.

The connecting member 3 comprises a head 31 and a shank 32 extending from one side of the head 31. The shank 32 is used to be inserted into the positioning hole 220 of the fastening member 22, and the head 31 is exposed to the outside of the fastening member 22. The connecting member 3 further comprises a screw rod 33 extended from the shank 32 opposite to the head 31. Use the screw rod 33 to pass through the shaft hole 210 of the rotating member 21, and pass through the through hole 110 of the base body 11 of the base 1, and then lock it in the locking screw hole 120 of the positioning member 12, so that it can move up and down inside rotating member 21, base body 11 and positioning member 12.

The base body 11 of the base 1 of the present invention further comprises a lower limit stop wall 1111 on one side, a higher limit stop wall 1112 on the other side, and a limit hole 1101 with reduced diameter provided on the one end of the through hole 110 near the higher limit stop wall 1112. The slideway 111 extends spirally from the lower limit stop wall 1111 to the higher limit stop wall 1112. The side of the insertion rod 211 of the rotating member 21 of the movable seat 2 that penetrates into the through hole 110 is provided with an expansion ring body 2111, which can be held against the inner side of the limit hole 1101 to form a limit. The other side of the through hole 110 can be used for fastening and embedding of the meshing teeth 1211 of the joint portion 121 of the positioning member 12. The diameter of the through hole 110 of the base body 11 is smaller than the outer diameter of the joint portion 121 of the positioning member 12.

In the above-mentioned movable seat 2 of the present invention, the bottom side of the rotating member 21 is protruded with the insertion rod 211 that reduces the diameter, and the bottom side of the rotating member 21 is also provided with the sliding rod 212 extending in the same direction as the insertion rod 211. The top of the rotating member 21 is provided with a ring convex 214 outside the shaft hole 210, and the above-mentioned accommodating groove 213 is recessed in the ring convex 214 for the fastening member 22 to be embedded in a tight fit position. The shank 32 of the connecting member 3 can be mounted with a gasket 34, and the diameter of the gasket 34 is larger than the outer diameter of the ring convex 214.

The above-mentioned connecting member 3 of the present invention can be a screw or a screw rod, etc., and the shank 32 on one side is passed through the positioning hole 220 of the fastening member 22 to form a tight fit, so that the fastening member 22 and the rotating member 21 can rotate and displace along with the connecting member 3. The fastening member 22 can be made of flexible materials such as soft plastic, silicone, rubber or nylon.

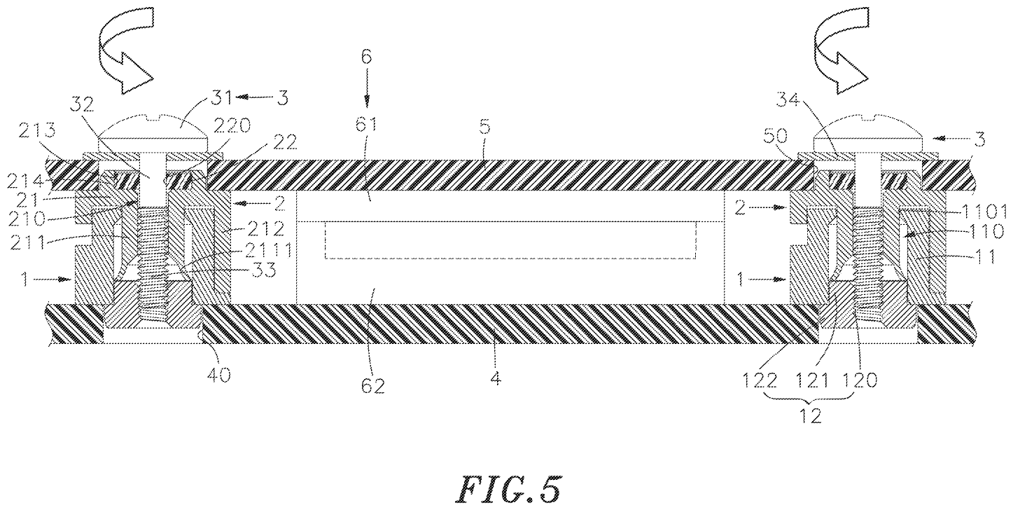

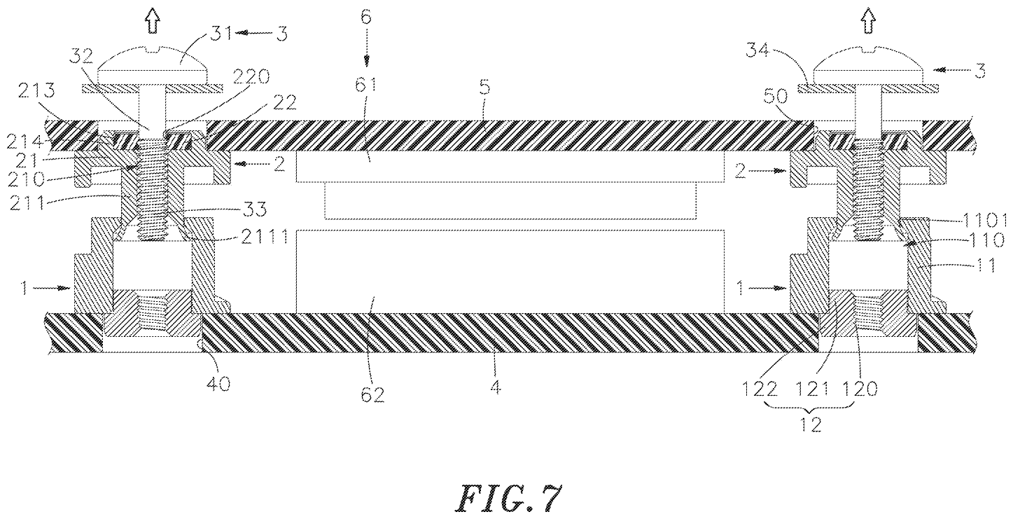

Please refer to FIGS. 1 to 8, when the board assembly device of the present invention is actually applied and implemented, the positioning member 12 of base 1 is assembled and positioned at the first fixing hole 40 of the preset first board member 4 with the fixed portion 122 (the assembly and positioning can be performed by means of welding, riveting or glue fixing), the ring convex 214 of the rotating member 21 of the movable seat 2 is put into the second fixing hole 50 of the preset second board member 5, and then the screw rod 33 of the connecting member 3 is passed through the positioning hole 220 of fastening member 22 to tightly fit and fix the shank 32 at the positioning hole 220, so that the gasket 34 placed at the shank 32 is attached to the outside of the second fixing hole 50 of the preset second board member 5, and then the screw rod 33 is passed through the shaft hole 210 of the rotating member 21 to extend out of the shaft hole 210 and pass through the through hole 110, so as to be locked at the locking screw hole 120 of the positioning member 12.

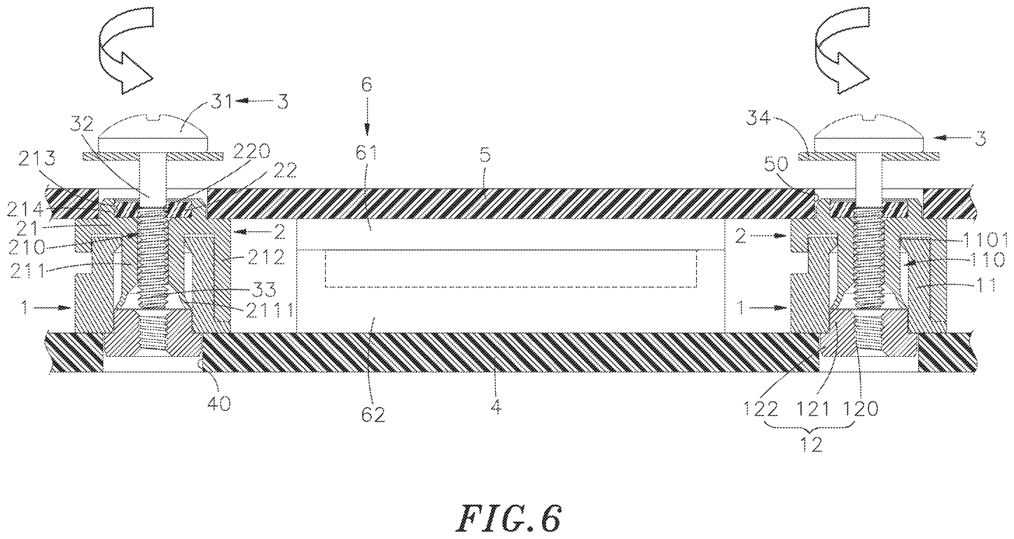

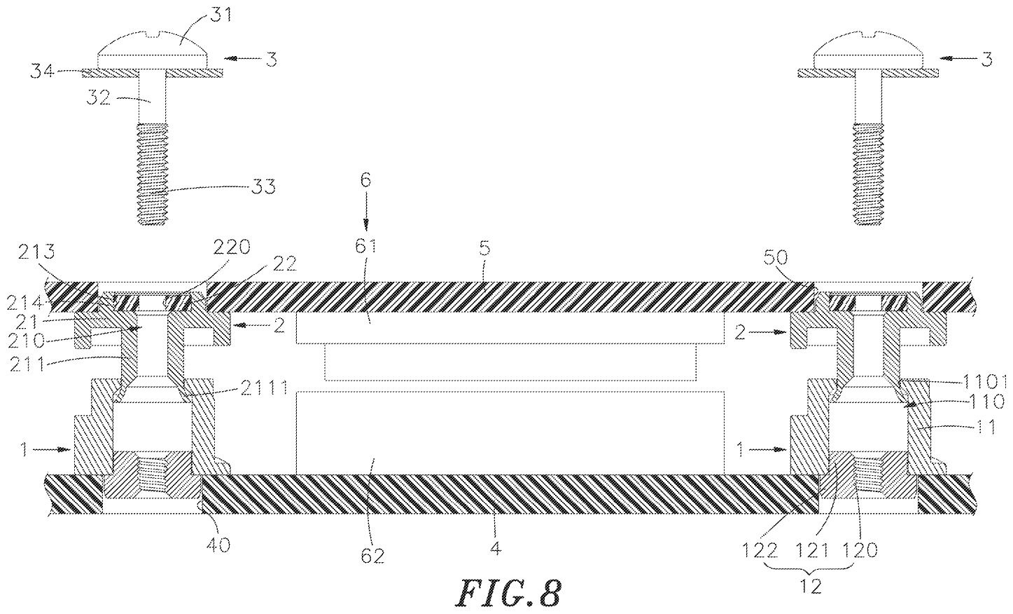

The connecting member 3 can be rotated by using a preset hand tool (it can be a screwdriver, etc., not shown in the figures) to drive the rotating member 21 of the movable seat 2, so as to drive the sliding rod 212 of the rotating member 21 sliding down along the slideway 111 of the base body 11 of the base 1 to the position to stop against the lower limit stop wall 1111. At the same time, the two board-to-board connectors 61 and 62 (male plug and female socket) between the preset first board member 4 and the preset second board member 5 are docked and plugged for electrical connection, so that the preset first board member 4 and the preset second board member 5 are in a stable assembly and combination for transmitting electronic signals or power through the two board-to-board connectors 61 and 62. When the connecting member 3 is reversely rotated by using a preset hand tool (it can be a screwdriver, etc., not shown in the figures), the screw rod 33 is rotated up at the locking screw hole 120 of the positioning member 12, and after passed the through hole 110 of base body 11, it rotates up to the shaft hole 210 of rotating member 21. When the top of the screw rod 33 rotates to form an interference clamp with the fastening member 22 (Please also refer to FIG. 6, and the fastening member 22 is made of elastic soft material, such as plastic, silicone, rubber or nylon, etc., which has better elastic recovery force and can reduce the damage caused by the screw rod 33 when it rotates through), the interference resistance generated between the screw rod 33 and the fastening member 22 will be greater than the rotational torque between the movable seat 2 and the base 1, that is to say, the screw rod 33 of the connecting member 3 is linked with the fastening member 22 to drive the sliding rod 212 on the side of the rotating member 21 to rotate and rise along the slideway 111 from the position of the lower limit stop wall 1111 to the position of the higher limit stop wall 1112, and at the same time drive the rotating member 21 push the preset second board member 5 to rise away from the preset first board member 4. Then the insertion rod 211 of the rotating member 21 also rises in the through hole 110 of the base body 11. When the side of the sliding rod 212 is held against the position of the higher limit stop wall 1112, the expansion ring body 2111 on the side of insertion rod 211 can be held against the top of the through hole 110 inside the limit hole 1101, and it can also prevent the rotating member 21 from detaching from the base body 11. And the rotating member 21 pushes the board-to-board connectors 61 and 62 (male plug and female socket) between the preset second board member 5 and the preset first board member 4 to separate. That is, the screw rod 33 of the connecting member 3 can be rotated and withdrawn from the exterior of the fastening member 22 by using the preset hand tool (not shown in the figures) (please also refer to the FIG. 8) for the connecting member 3 and the base 1, the movable seat 2 to form a separated and unlocked state. This achieves the purpose of conveniently operating the rotating member 21 to rotate and lift at the base body 11, and to drive the assembly or separation of the board-to-board connectors 61 and 62 of the electrical connector module 6 by interlocking the preset second board member 5. It is convenient for docking or separation between the two board-to-board connectors 61 and 62, without collision or pushing between the preset first board member 4 and the preset second board member 5, so as to maintain a good assembly state between the preset first board member 4, the preset second board member 5, and the two relative board-to-board connectors 61 and 62, and have the effect of extending the service life.

The above description is only a preferred embodiment of the present invention, and does not limit the patent scope of the present invention. Therefore, all simple modifications and equivalent structural changes made by using the contents of the description and drawings of the present invention should be included in the patent scope of the present invention in the same way, and are hereby declared.

To sum up, the above board assembly device and its assembly method of the present invention can really achieve its effect and purpose when used, so the present invention is an invention with excellent practicability. In order to meet the application requirements for invention patents, an application is filed in accordance with the law. I hope that the review committee will approve this case as soon as possible to protect the hard work of the inventor. If the review committee has any doubts, please feel free to write to us, and the inventor will do his best to cooperate.

What the invention claimed is:

1. A board assembly device, comprising a base, a movable seat, and a connecting member, wherein:
said base comprises a base body and a positioning member assembled at a bottom of said base body, said base body comprising a through hole inside and a slideway extending obliquely in a spiral shape on an outside, said positioning member comprising a joint portion assembled and positioned on one end of said through hole, a fixed portion located on one side of said joint portion and stopped outside said through hole and a locking screw hole provided therein;
said movable seat is movably assembled an outside said base body, said movable seat comprising a rotating member and a fastening member, said rotating member comprising an insertion rod extended from a bottom side thereof for penetrating into said through hole of said base body, a sliding rod extended from the bottom side and spaced from said insertion rod at one side for sliding along said slideway of said base body, a shaft hole located in said insertion rod and an accommodating groove recessed on an opposing top side thereof for embedding and fixation of said fastening member, said fastening member having a positioning hole formed therein;
said connecting member comprises a head and a shank extending from one side of said head, said shank being used to be inserted into said positioning hole of said fastening member, said head being exposed to an outside of said fastening member, said connecting member further comprising a screw rod extended from said shank opposite to said head, said screw rod passing through said shaft hole of said rotating member, and passing through said through hole of said base body of said base, and then being locked in said locking screw hole of said positioning member.

2. The board assembly device as claimed in claim 1, wherein said base body of said base further comprises a lower limit stop wall on one side, a higher limit stop wall on an opposite side, and a limit hole with reduced diameter provided on one end of said through hole near said higher limit stop wall; said slideway extends spirally from said lower limit stop wall to said higher limit stop wall; a side of said insertion rod of said rotating member of said movable seat that penetrates into said through hole is provided with an expansion ring body, which is to be held against an inner side of said limit hole to form a limit, and the other side of said through hole is to be used for fastening and embedding of said joint portion of said positioning member.

3. The board assembly device as claimed in claim 2, wherein a diameter of said through hole of said base body is smaller than an outer diameter of said joint portion of said positioning member; said joint portion is provided with a plurality of meshing teeth for fastening and embedding in said through hole.

4. The board assembly device as claimed in claim 1, wherein the bottom side of said rotating member is protruded with said insertion rod that reduces a diameter, and the bottom side of said rotating member is also provided with said sliding rod extending in a same direction as said insertion rod.

5. The board assembly device as claimed in claim 1, wherein said rotating member further comprises a ring convex located on a top side thereof outside said shaft hole, and said accommodating groove is recessed in said ring convex for said fastening member to be embedded in a tight fit position; said shank of said connecting member is mounted with a gasket, and a diameter of said gasket is larger than an outer diameter of said ring convex.

6. The board assembly device as claimed in claim 5, wherein said shank of said connecting member is passed through a positioning hole of said fastening member to form a tight fit for said fastening member and said rotating member to rotate and displace along with said connecting member; said fastening member is made of a flexible material selected from a group of soft plastic, silicone, rubber and nylon.

7. The board assembly device as claimed in claim 1, wherein said screw rod of said connecting member rises to form an interference clamp with said fastening member and produce an interference resistance greater than the rotational torque between said movable seat and said base when said connecting member is rotated reversely.
